(19) United States
(12) Patent Application Publication
(10) Pub. No.: US 2005/0156333 A1
(43) Pub. Date: Jul. 21, 2005

(54) Narrow Universal-Serial-Bus (USB) Flash-Memory Card with Straight Sides using a Ball-Grid-Array (BGA) Chip

(75) Inventors: Ren-Kang Chiou, Fremont, CA (US); Jim Chin-Nan Ni, San Jose, CA (US)

Correspondence Address: STUART T AUVINEN, 429 26TH AVENUE, SANTA CRUZ, CA, 95062-5319, US

(73) Assignee: SUPER TALENT ELECTRONICS INC., San Jose, CA (US)

(21) Appl. No.: 10/907,204

(22) Filed: Mar. 24, 2005

Related U.S. Application Data
(63) Continuation-in-part of application No. 10/605,146, filed on Sep. 11, 2003, now Pat. No. 6,854,984.
(63) Continuation-in-part of application No. 10/904,207, filed on Oct. 28, 2004.

(51) Int. Cl. H01L 23/28

(52) U.S. Cl. 257/787; 257/723

(57) ABSTRACT

A narrow flash-memory-drive card has an integrated slim Universal-Serial-Bus (USB) connector that fits into a standard USB socket. The slim USB connector has 4 metal contacts on a board that is encapsulated by a plastic case. Components are mounted onto the board on the side opposite the metal contacts. The flash-memory drive card is as narrow as the USB connector, with straight edges, since a narrow flash-memory chip is used that is packaged in a more area-efficient Ball Grid Array (BGA) package that has solder-ball connections in a two-dimensional array rather than leads around a perimeter. The BGA package and board are covered by a plastic case and a cover. The cover and case can be bonded together ultrasonically, with adhesive films, or using snaps. The cover and/or plastic case can also be formed by a molding process.

### RELATED APPLICATIONS

This application is a continuation-in-part of the co-pending application for “Slim USB Connector with Spring-Engaging Depressions, Stabilizing Dividers and Wider End Rails for Flash-Memory Drive”, U.S. Ser. No. 10/605,146, filed Sep. 19, 2003, now U.S. Pat. No. 6,854,984, and “Manufacturing Methods for Ultra-Slim USB Flash Memory Card with Supporting Dividers or Underside Ribs”, U.S. Ser. No. 10/904,207, filed Oct. 28, 2004.

### FIELD OF THE INVENTION

This invention relates to reduced-size Universal-Serial-Bus (USB) connectors, and more particularly to flash-memory-drive cards using Ball Grid Array (BGA) chips.

### BACKGROUND OF THE INVENTION

Flash-memory technologies such as those using electrically-erasable programmable read-only memory (EEPROM) have produced chips storing 1 G-Bytes or more. Small flash-memory cards have been designed that have a connector that can plug into a specialized reader, such as for compact-flash, secure-digital, memory stick, or other standardized formats.

Recently, flash memory cards are being sold that contain a USB connector. Such USB-flash memory cards do not require a specialized reader but can be plugged into a USB connector on a personal computer (PC) or other hosting device. These USB-flash memory cards can be used in place of floppy disks and are known as USB key drives, USB thumb drives, and a variety of other names. These USB-flash cards can have a capacity of more than ten floppy disks in an area not much larger than a large postage stamp.

FIG. 1 shows a bottom view of assembly of a male slim USB connector that is integrated with a circuit-board substrate of a flash memory card. Flash memory chip 75 may be a 128 Mega-byte non-volatile chip or may have some other capacity. Controller chip 78 contains a flash-memory controller that generates signals to access memory locations within flash memory chip 75. Controller chip 78 also contains a USB interface controller that serially transfers data to and from flash memory chip 75 over a USB connection.

A USB connector may be formed on board 60, which is a small circuit board with chips 75, 78 mounted thereon. Multi-layer printed-circuit board (PCB) technology can be used for board 60. Metal contacts carry the USB signals generated or received by controller chip 78. USB signals include power, ground, and serial differential data D+, D−.

The USB flash-memory card is assembled from PCB board 60 and its components, and lower case 64, which are sandwiched together to form the flash-memory card. The bottom surface of board 60 is visible in FIG. 1.

Flash memory chip 75 and controller chip 78 are mounted on the reverse (bottom) side of board 60, which can be a multi-layer PCB or similar substrate with wiring traces. The 4 USB contacts are formed on the top side of board 60 and are not visible in this bottom view. Since most components are mounted on the bottom side of board 60 opposite the top side with the USB metal contacts, board 60 does not need a plastic cover over its top side. This allows the flash-memory card to have a lower profile or even a co-planar top surface.

Extension 61 of board 60 has a width that approximately matches the width of the connector substrate and the metal wrap in a male USB connector, about 12.4 mm. Metal USB contacts (not visible) are formed on the top side of extension 61 to act as the USB metal contacts of the male slim USB connector. End 72 of board 60 is inserted into the female USB connector.

Lower case 64 also includes extended region 80. LED 93 can be mounted on board 60, such as on the bottom side with other components, or extending from an edge of board 60.

The relatively large size of flash memory chip 75 may require that board 60 be widened beyond extension 61. The width of flash memory chip 75 may be wider than 12.4 mm, thus requiring the widening of board 60 beyond extension 61. Flash memory chip 75 may be contained within a thin-small-outline package (TSOP) or other surface-mount package that is still relatively larger than a USB connector and extension 61.

The width of flash memory chip 75 thus increases the width of the USB flash-memory drive, causing a flared or T-shape to the device. This widening of the USB flash-memory device is undesirable.

What is desired is a narrower USB flash-memory device. A USB flash-memory device with a straight edge extending from the USB connector is desirable.

### BRIEF DESCRIPTION OF THE DRAWINGS

FIG. 1 shows a bottom view of assembly of a male slim USB connector that is integrated with a circuit-board substrate of a flash memory card.

FIGS. 2A-C show a narrow USB flash-memory device with straight edges that uses a flash-memory chip in a BGA package.

FIGS. 3A-D show a narrow USB device made with a heating/cooling press method.

FIG. 4 is an enlarged view of the USB connector end of the device of FIGS. 3A-D.

FIGS. 5A-D show 3-piece assembly using an ultrasonic welding process.

FIGS. 6A-B show 3-piece assembly using a snap-together process.

FIGS. 7A-B show a 1-step molding process.

FIGS. 8A-B show 1-step molding using a molding fixture.

FIGS. 9A-B show a 2-step molding process.

FIG. 10 shows the second molding step of the 2-step molding process using a molding fixture.

FIG. 11 is a cross-section of an alternate embodiment with BGA chips mounted to both sides of the board.

FIG. 12 is a cross-section of an alternate embodiment with BGA chips mounted to both sides of the board and a cover over the USB pads.

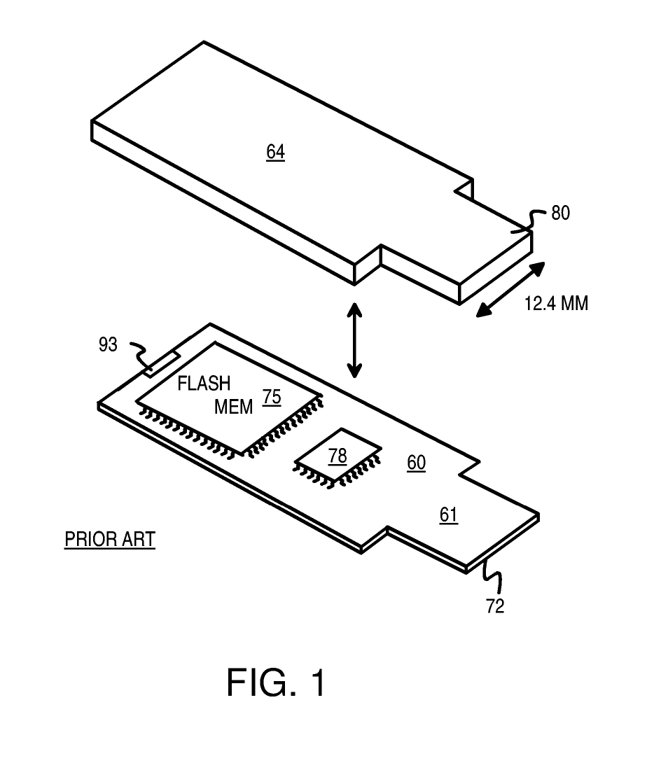

### DETAILED DESCRIPTION

The present invention relates to an improvement in small USB flash drives. The following description is presented to enable one of ordinary skill in the art to make and use the invention as provided in the context of a particular application and its requirements. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

The inventors have realized that the flash memory chip can limit the narrowness of a USB flash-memory device. Reducing the width of the packaged flash memory chip can allow for a narrower, smaller USB flash-memory device.

Ball Grid Array (BGA) packages have an array or grid of solder balls on the bottom-side surface of the package. Since the solder balls are in a 2-D array, more connections can be made for a specified package area that when connection leads are placed around the perimeter of a package. Thus BGA packages can have a more area-efficient interconnect than packages with connections only on the perimeter.

For a given number of connection pins, a BGA package can have a smaller area than a package with leads or connections around the perimeter. The inventors have realized that using a BGA package for the flash memory chip rather than a TSOP or other perimeter-pin package can reduce the package area. Using a smaller BGA package for the flash memory chip can allow for a narrower USB device.

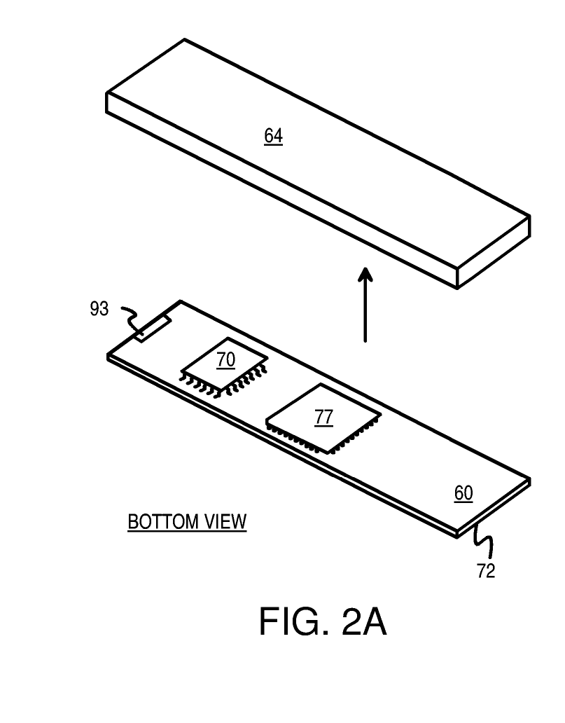

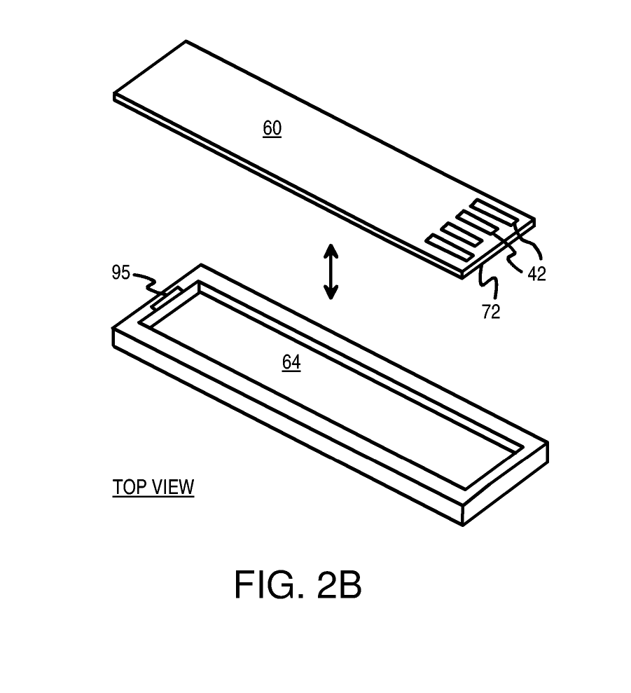

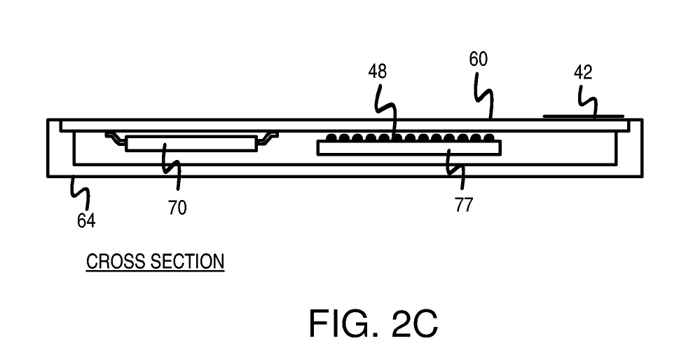

FIGS. 2A-C show a narrow USB flash-memory device with straight edges that uses a flash-memory chip in a BGA package. Flash memory chip 77 is a BGA package with a 128 Mega-byte non-volatile memory chip or may have a die with some other capacity. Controller chip 70 contains a flash-memory controller that generates signals to access memory locations within flash memory chip 77. Controller chip 70 also contains a USB interface controller that serially transfers data to and from flash memory chip 77 over a USB connection.

Since flash memory chip 77 is a BGA package, it can have a small area as the solder-ball connections are in a 2-D array. For example, a BGA memory chip having dimensions of 8.5 mm by 13 mm may be used for flash memory chip 77. Since the narrowest dimension, 8.5 mm, is less than the width of the USB connector, 12.4 mm, flash memory chip 77 does not require a widening of board 60. Instead, board 60 can be 12.4 mm wide for its entire length.

Multi-layer printed-circuit board (PCB) technology can be used for board 60. Metal contacts carry the USB signals generated or received by controller chip 70. USB signals include power, ground, and serial differential data D+, D−.

The USB flash-memory card is assembled from PCB board 60 and its components, and lower case 64, which are sandwiched together to form the flash-memory card. The bottom surface of board 60 is visible in FIG. 2A.

Flash memory chip 77 and controller chip 70 are mounted on the reverse (bottom) side of board 60, which can be a multi-layer PCB or similar substrate with wiring traces. The 4 USB contacts are formed on the top side of board 60 and are not visible in this bottom view.

Board 60 has a width that approximately matches the width of the connector substrate and the metal wrap in a male USB connector, about 12.4 mm. Metal USB contacts (not visible) are formed on the top side of board 60 to act as the USB metal contacts of the male slim USB connector. End 72 of board 60 is inserted into the female USB connector.

LED 93 can be mounted on board 60, such as on the bottom side with other components, or extending from an edge of board 60.

FIG. 2B shows the top view of the straight-edge USB memory device of FIG. 2A. The 4 USB contacts, metal contacts 42, are formed on the top side of board 60. Since most components (not visible in FIG. 2B) are mounted on the bottom side of board 60, board 60 does not need a plastic cover over its top side. This allows the flash-memory card to have a lower profile or even a co-planar top surface.

Board 60 has a width that approximately matches the width of the connector substrate and the metal wrap in a male USB connector. Metal contacts 42 are formed on the top side of board 60 to act as the USB metal contacts of the male slim USB connector. End 72 of board 60 is inserted into the female USB connector.

Lower case 64 can have grooves in its sidewalls to accept board 60 during assembly. Board 60 can be attached to lower case 64 by adhesive or by snap fasteners, such as plastic snap pins or tabs in lower case 64 that fit through and lock into holes in board 60. Adhesive could be a thermal-bond or another type.

A region of reduced thickness is formed in lower case 64 to create light window 95. Light window 95 could be formed on the back wall of lower case 64 as shown, or could be formed on the larger bottom surface of lower case 64 or on some other area of lower case 64. Light from LED 93 on board 60 (FIG. 2A) can partially pass through the thinner plastic of light window 95, allowing the user to see a visible indicator of activity. A light guide or pipe could also be used to channel the light path to light window 95.

FIG. 2C is a cross-section of the narrow USB device of FIGS. 2A-B. Board 60 fits into lower case 64. Lower case 64 covers flash memory chip 77 and controller chip 70, which are mounted on the bottom side of board 60. While controller chip 70 can be a standard small-outline or other leaded or leadless chip package with leads around the perimeter, flash memory chip 77 is mounted in a BGA package. Solder balls 48 are formed in an array on a surface of the BGA package for flash memory chip 77, and make electrical connection to board 60. The four USB contacts are formed by metal contacts 42 on the top surface of board 60. The top surface of board 60 is exposed while the bottom surface is covered by lower case 64.

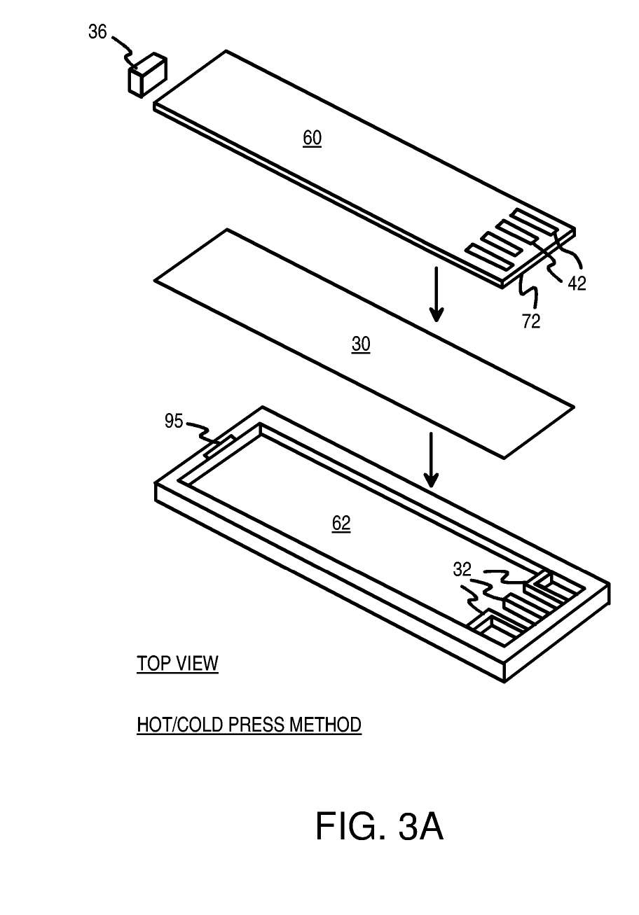

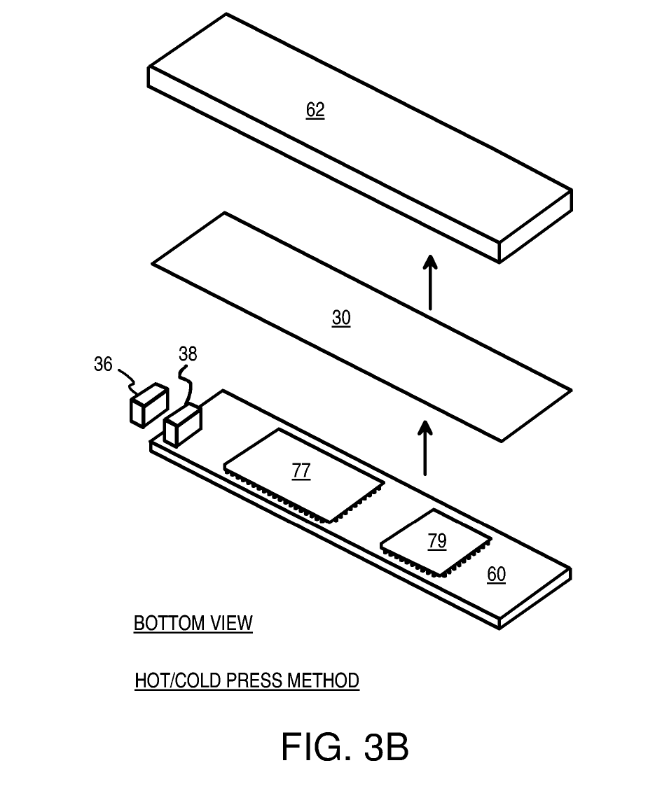

FIGS. 3A-D show a narrow USB device made with a heating/cooling press method. In the top view of FIG. 3A, board 60 has metal contacts 42 on top and is pressed into lower case 62 with film 30 in-between. Film 30 can be a thin sheet of thermal-bond film such as 3M's TBF-668 film. Board 60 is clamped into lower case 62 with film 30 in between and then heated to about 150 degrees C. for curing of film 30. Once heating is complete, the clamped assembly of board 60 and lower case 62 is allowed to cool before the clamps are removed from the final device assembly.

Litepipe 36 can be fitted into light window 95 in lower case 62 before assembly. Supporting ridges 32 in lower case 62 are located under board 60 near metal contacts 42 to provide additional support to insertion end 72 which forms the USB connector.

FIG. 3B shows the bottom view. LED 38 can be mounted on board 60 and is located near litepipe 36 once assembled. Flash memory chip 77 in a BGA package and controller chip 70 are mounted to the bottom surface of board 60 and are protected by lower case 62, which adheres to board 60 once film 30 is heated and cured.

FIG. 3C shows the bottom view of the assembly after heating, cooling, and removal of clamps. Lower case 62 is seen covering board 60. FIG. 3D shows the top view of the final assembly, with board 60 and metal contacts 42 visible.

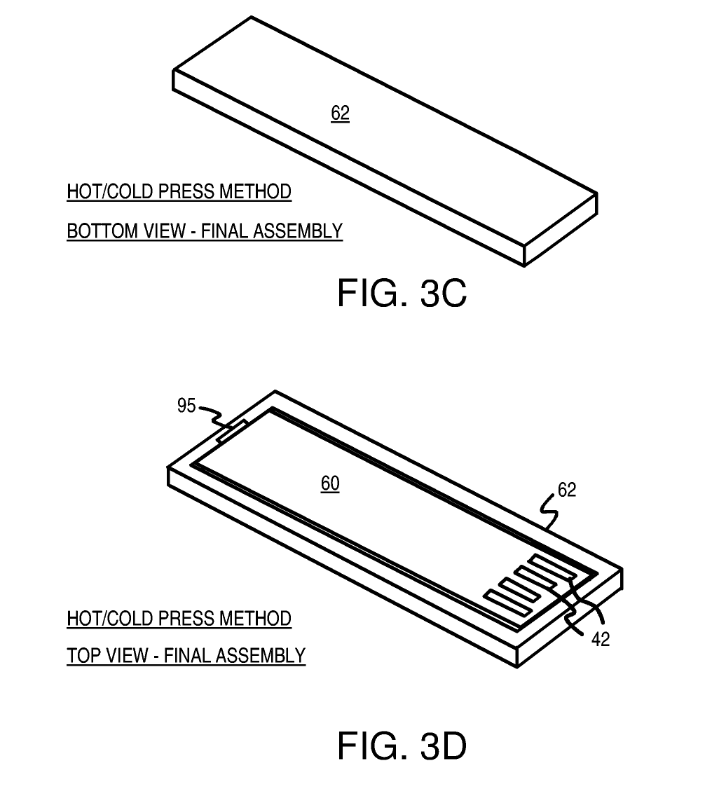

FIG. 4 is an enlarged view of the USB connector end of the device of FIGS. 3A-D. The four USB contacts are metal contacts 42 formed on the top surface of board 60. Board 60 fits within lower case 62, which forms the side and end edges of the USB connector of insertion end 72. Insertion end 72 can be inserted into a USB socket and metal contacts 42 make electrical contact with USB springs or metal in the USB socket.

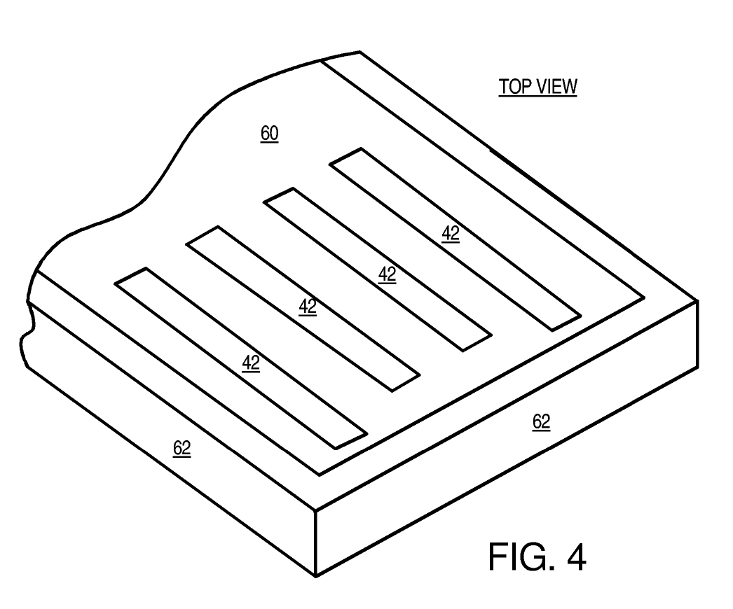

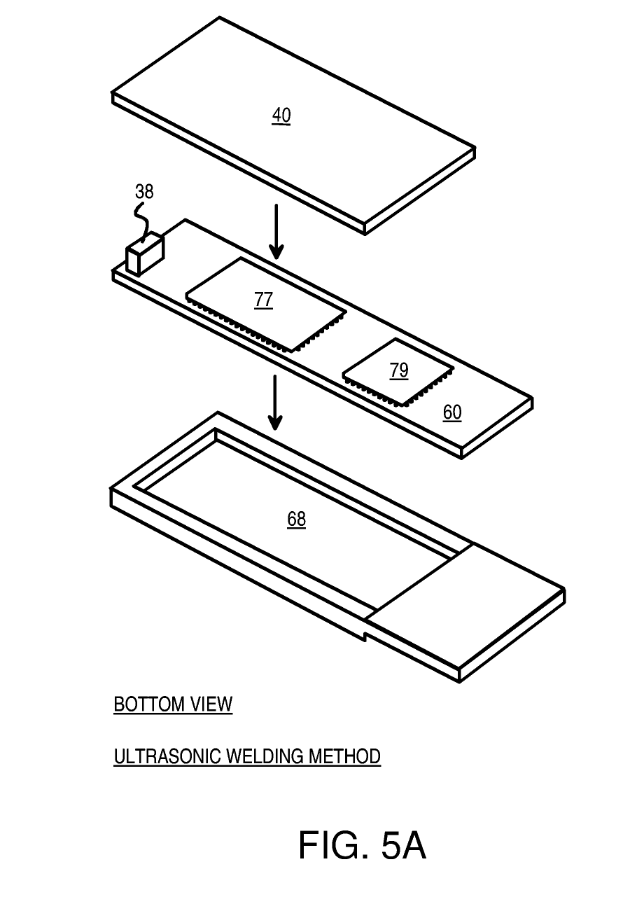

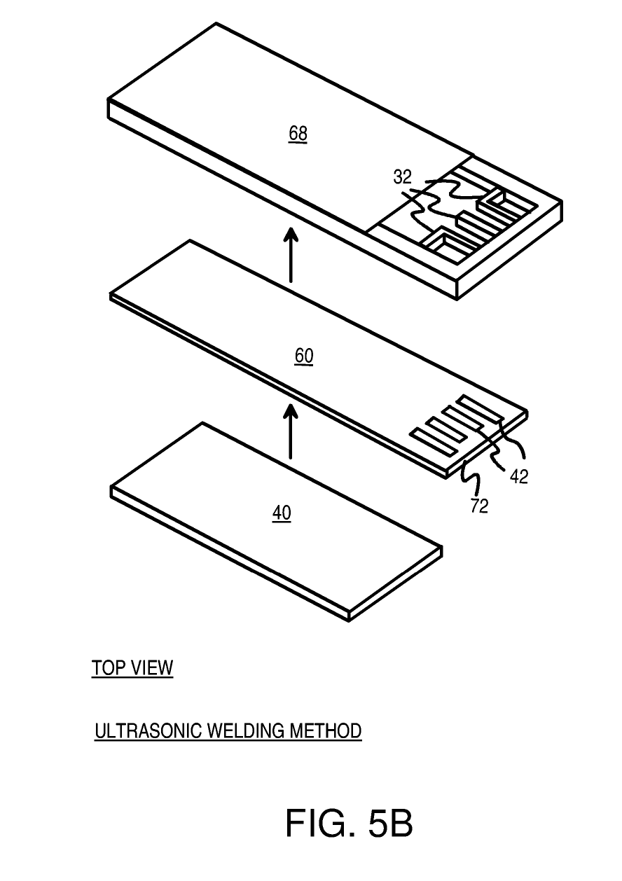

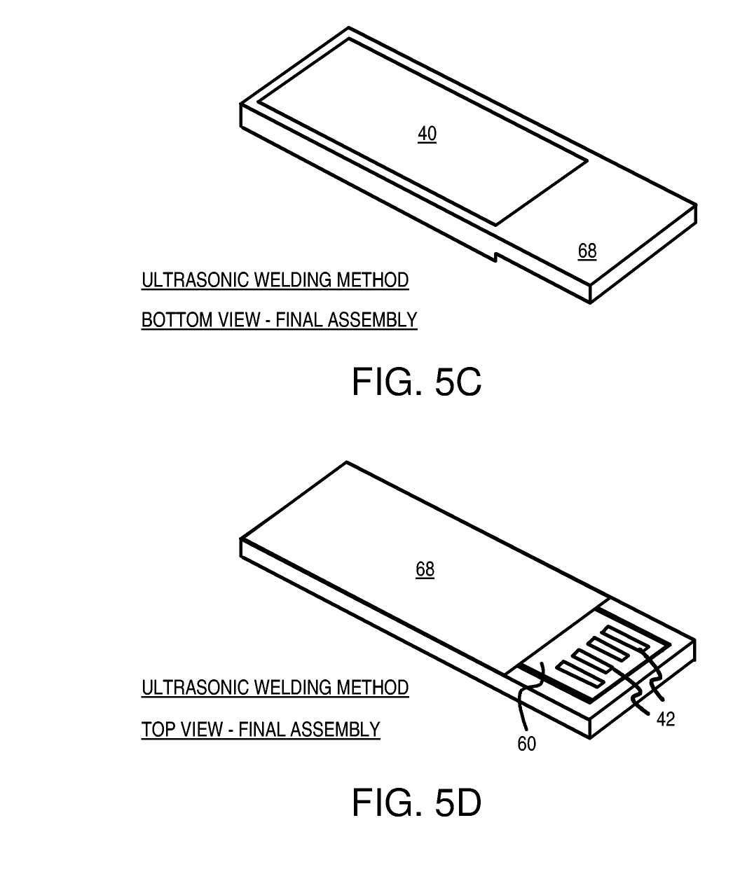

FIGS. 5A-D show 3-piece assembly using an ultrasonic welding process. In the bottom view of FIG. 5A, board 60 is tilted at an angle and has its USB end inserted into case 68. Then board 60 is pushed flat into case 68 and cover 40 is placed over board 60 to cover the large bottom opening in case 68. LED 38 can be mounted on board 60. Flash memory chip 77 in a BGA package and controller chip 70 are mounted to the bottom surface of board 60 and are protected by case 68.

In the top view of FIG. 5B, case 68 has a smaller top opening that expose metal contacts 42 on the top surface of board 60 after assembly. Supporting ridges 32 are visible inside the smaller opening of case 68 and provide mechanical support to the USB connector of insertion end 72 to prevent damage by rough usage.

Once board 60 is inserted into case 68, and cover 40 is attached, the assembly can be placed in an ultrasonic welding fixture and ultrasonic energy applied. The ultrasonic energy vibrates the parts at high frequency, causing heating at contact points such as ultrasonic ridges (not shown) that can be formed on case 68 or cover 40 at points of contact. These ridges melt under the ultrasonic energy, forming a plastic bonding between case 68 and cover 40.

FIG. 5C shows the bottom view of the final assembly, with cover 40 welded into the larger opening in case 68. FIG. 5D shows the top view of the final assembly, with metal contacts 42 visible in the small opening in case 68 that exposes part of board 60.

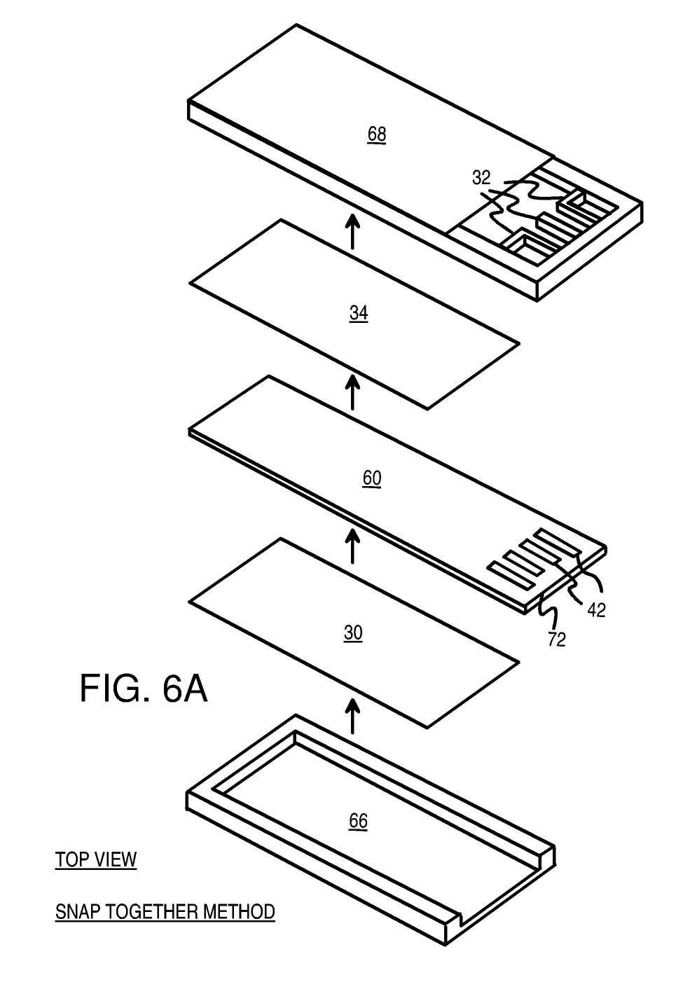

FIGS. 6A-B show 3-piece assembly using a snap-together process. In the top view of FIG. 6A, case 68 has a smaller top opening that expose metal contacts 42 on the top surface of board 60 after assembly. Supporting ridges 32 are visible inside the smaller opening of case 68 and provide mechanical support to the USB connector of insertion end 72 to prevent damage by rough usage.

In the bottom view of FIG. 6A, board 60 is tilted at an angle and has its USB end inserted into case 68. Then board 60 is pushed flat into case 68 and cover 66 is placed over board 60 to cover the large bottom opening in case 68. LED 38 can be mounted on board 60. Flash memory chip 77 in a BGA package and controller chip 70 are mounted to the bottom surface of board 60 and are protected by case 68.

Adhesive film 30 can be placed inside cover 66, and film 34 can be placed inside case 68 before board 60 is fitted into case 68 and cover 66 attached and snapped into place. Protective backing from films 30, 34 can be peeled off just before attachment, and double-sided adhesive films may be used. Adhesive films 30, 34 may be pressure-sensitive or heat-sensitive, but may not be used in all embodiments, such as when snaps are fully secure.

Cover 66 may fit inside case 68 or may fit around the outside of case 68. Various types of plastic snaps and mating grooves may be formed on case 68 and cover 66 but are not shown due to their typically smaller size. Plastic snap tabs may be semi-flexible plastic extensions or protrusion tabs formed on the edges of cover 66 or case 68 and extend upward or downward. Holes may be formed on the peripheral edges of cover 66 and match positions of plastic snap tabs in case 68.

The peripheral outline of cover 66 may be somewhat smaller than for case 68 so that cover 66 can fit inside case 68. During assembly, when board 60 is placed inside case 68, the edge of board 60 may be forced into grooves in the side walls of case 68, which can be covered with adhesive or can have snap tabs that snap through holes in board 60 when board 60 is fully inserted into case 68. This locks board 60 into case 68. A variety of shapes can be used for plastic snap tabs and grooves.

The final assembly is somewhat similar in appearance to the assembly of FIGS. 5C-D.

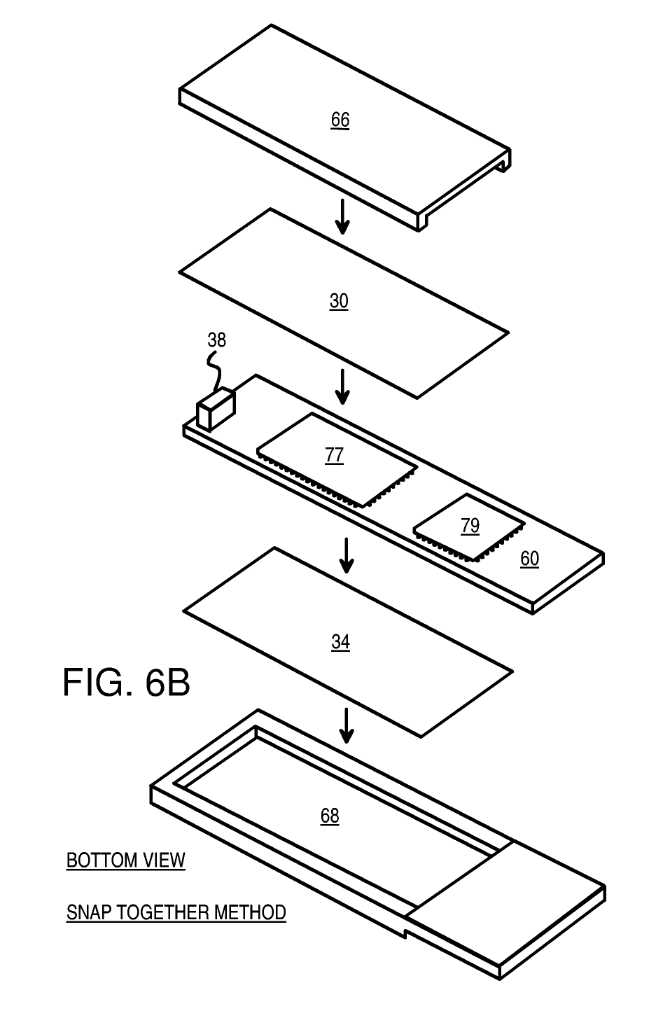

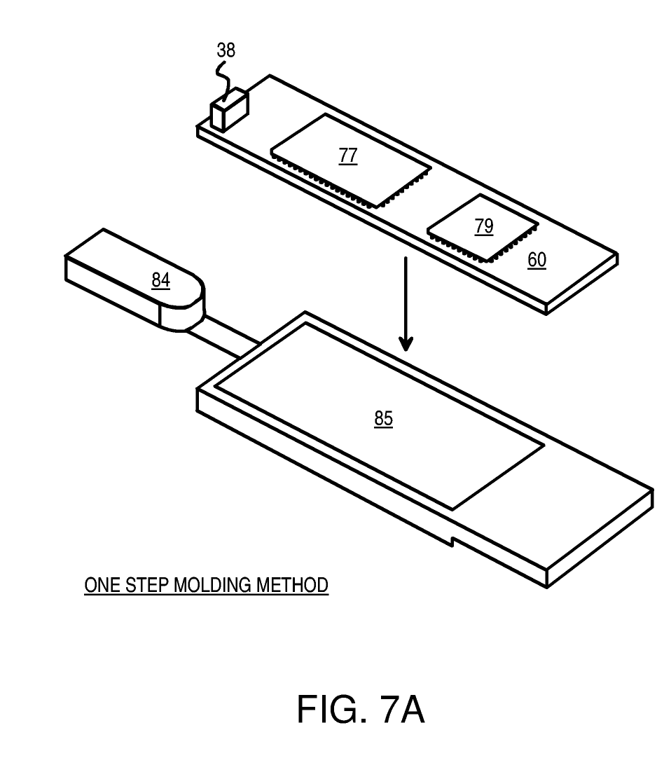

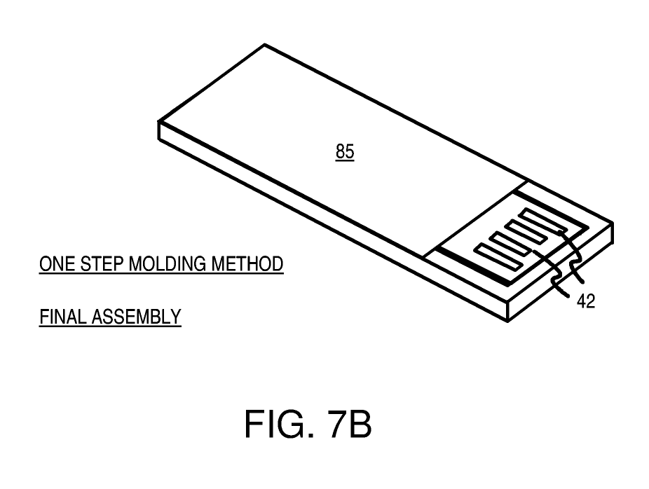

FIGS. 7A-B show a 1-step molding process. In FIG. 7A, board 60 has been assembled with flash memory chip 77 in a BGA package and controller chip 70 both mounted. LED 38 is also optionally mounted to board 60, and metal contacts 42 are formed on the (hidden) bottom side of board 60.

Assembled board 60 is placed in a molding fixture (not shown) and plastic is flowed into the fixture, around board 60. After cooling, the molded device is removed from the molding fixture and any burrs and molding handle 84 are removed to reveal the final assembled device that has molded plastic casing 85 that surrounds board 60. The molding fixture can prevent plastic from covering metal contacts 42 on board 60, as shown in the final assembled device in FIG. 7B.

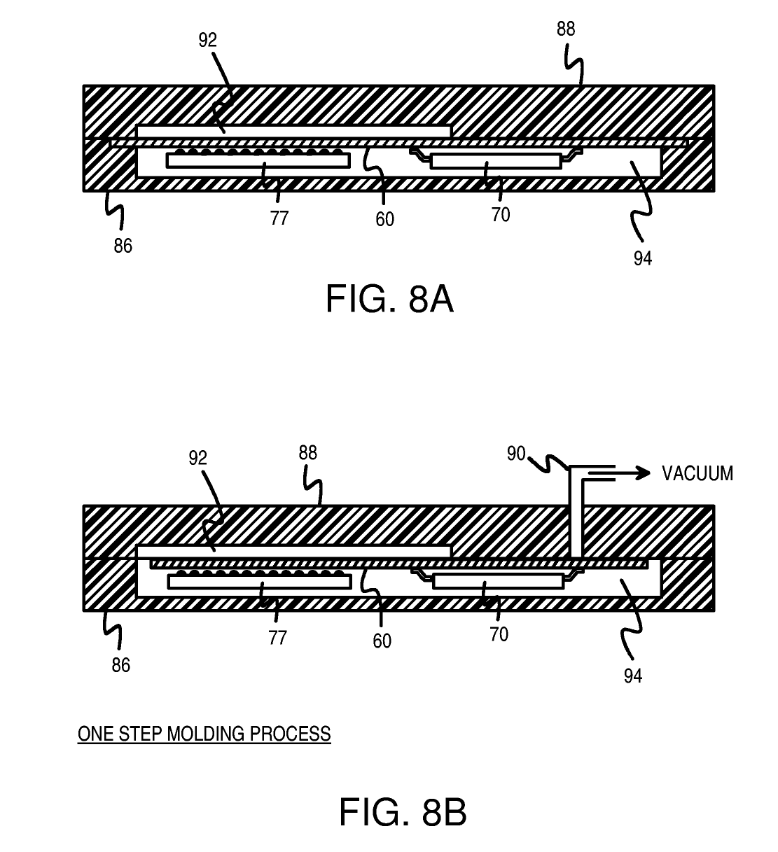

FIGS. 8A-B show 1-step molding using a molding fixture. In FIG. 8A, board 60 has its ends clamped between lower molding fixture 86 and upper molding fixture 88. The BGA package of flash memory chip 77 and controller chip 70 are below board 60 in lower air pocket 94 that is formed by the interior shape of lower molding fixture 86, while upper air pocket 92 is formed by the interior shape of upper molding fixture 88 above board 60.

During molding, plastic is squeezed, flowed, or extruded into upper air pocket 92 and into lower air pocket 94, encapsulating flash memory chip 77 and controller chip 70 and most of board 60. After cooling and removal from lower molding fixture 86 and upper molding fixture 88, molded plastic casing 85 encapsulates most of board 60, forming the case and cover. A single molding step forms molded plastic casing 85 which acts as both case and cover.

FIG. 8B shows an alternative molding fixture. Rather than clamp the ends of board 60, which may have to be trimmed or cut later, board 60 is held to upper molding fixture 88 by vacuum pressure by vacuum line 90. Upper air pocket 92 and lower air pocket 94 are connected around the left (non-insertion) end of board 60. Thus molded plastic casing 85 surrounds the non-insertion end of board 60 in this embodiment.

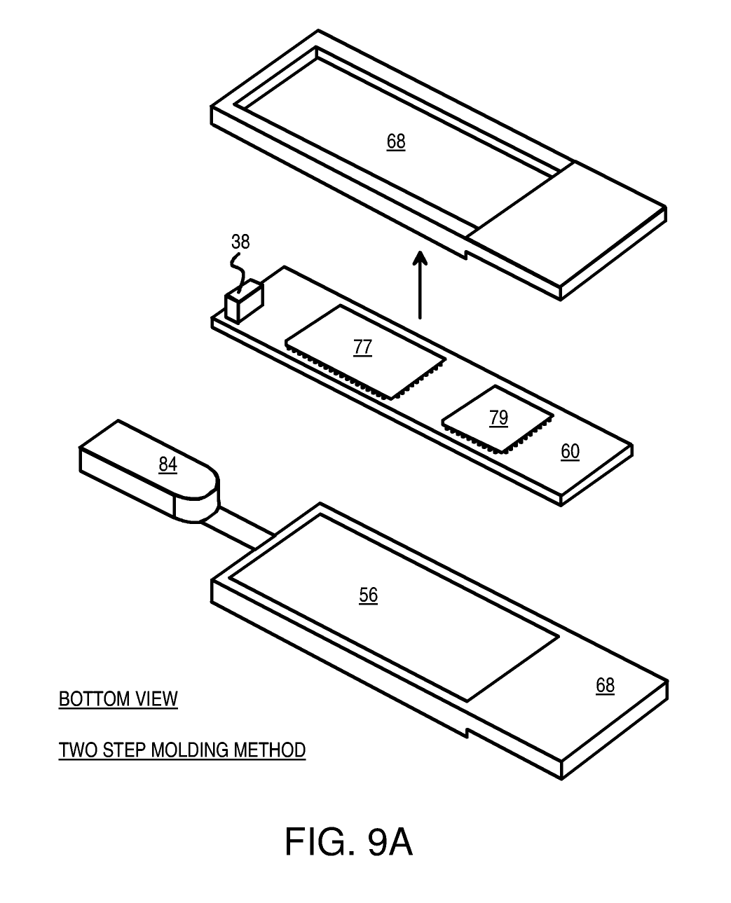

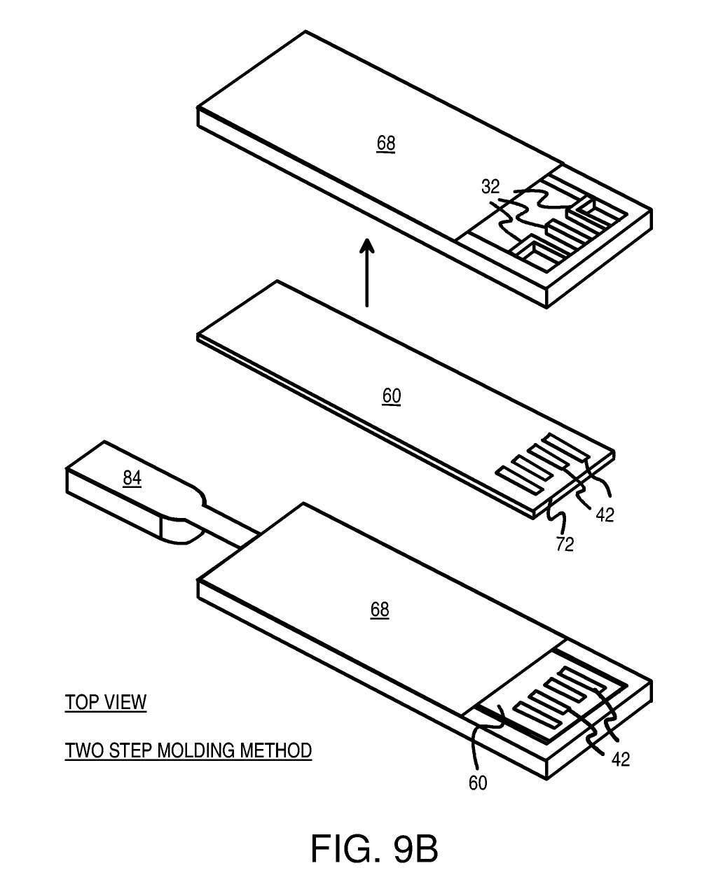

FIGS. 9A-B show a 2-step molding process. In FIG. 9A, board 60 has been assembled with flash memory chip 77 in a BGA package and controller chip 70 both mounted. LED 38 is also optionally mounted to board 60, and metal contacts 42 are formed on the (hidden) bottom side of board 60.

Assembled board 60 is tilted and inserted into an upper opening of case 68, which has previously been molded in a first molding step. Then board 60 and case 68 are placed in a molding fixture (not shown) and plastic is flowed into the fixture, around board 60 and case 68. This second molding step forms molded cover 56 over the large opening in case 68.

After cooling, the molded device is removed from the molding fixture and any burrs and molding handle 84 are removed to reveal the final assembled device that has molded plastic cover 56 molded into case 68 that surrounds board 60. The molding fixture can prevent plastic from covering metal contacts 42 on board 60, as shown in FIG. 9B. Supporting ridges 32 inside case 68 provide mechanical support to insertion end 72 or board 60 around metal contacts 42.

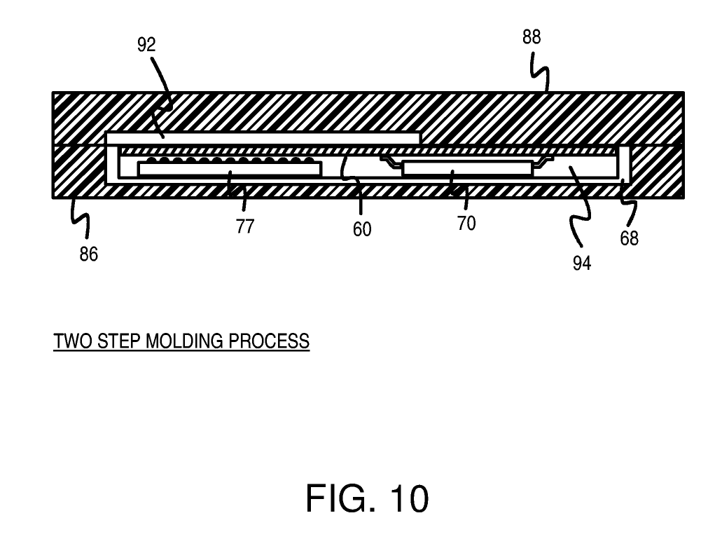

FIG. 10 shows the second molding step of the 2-step molding process using a molding fixture. Board 60 has been fitted into case 68 and are both placed between lower molding fixture 86 and upper molding fixture 88. Board 60 inside case 68 is held to upper molding fixture 88 by vacuum pressure by a vacuum line (not shown). The vacuum line can touch board 60 near metal contacts 42, which are exposed by case 68.

The BGA package of flash memory chip 77 and controller chip 70 are below board 60 inside case 68. Lower air pocket 94 is formed by the interior shape of case 68, while upper air pocket 92 is formed by the interior shape of upper molding fixture 88 above board 60 and case 68. Case 68 has a large opening (not shown) that board 60 was fitted through, and this opening allows plastic to reach flash memory chip 77 and controller chip 70 within case 68 during molding.

During molding, plastic is squeezed, flowed, or extruded into upper air pocket 92 and into lower air pocket 94, encapsulating flash memory chip 77 and controller chip 70 and most of board 60 into case 68. After cooling and removal from lower molding fixture 86 and upper molding fixture 88, case 68 formed by the first molding step and molded cover 56 formed by the second molding step encapsulate most of board 60, forming the case and cover.

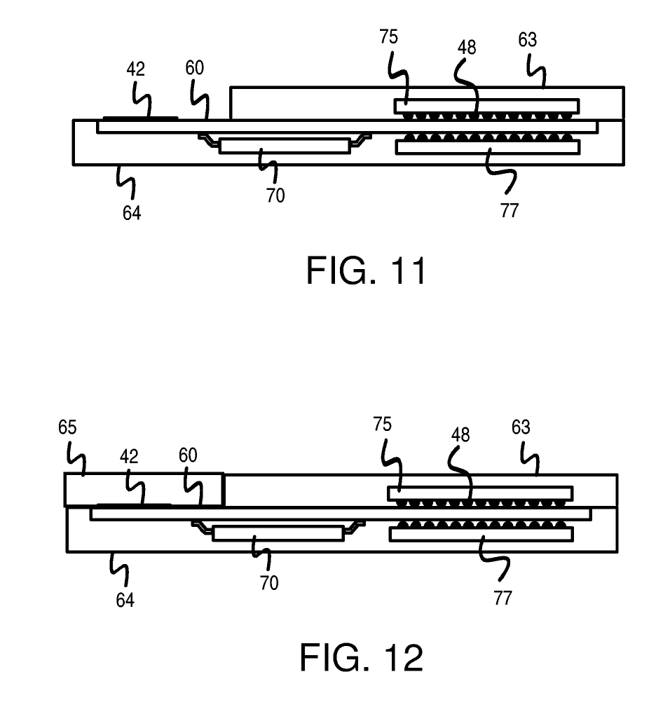

FIG. 11 is a cross-section of an alternate embodiment with BGA chips mounted to both sides of the board. Board 60 has controller chip 70 and BGA flash memory chip 77 mounted to the bottom side, with metal contacts 42 formed on the top side and exposed by upper case 63. Lower case 64 surrounds chips 70, 77.

Upper BGA chip flash memory chip 75 is a second flash memory chip that is mounted to the top side of board 60. This second flash-memory chip increases the storage capacity of the USB flash drive device. Solder balls 48 on the BGA packages are heated to solder flash memory chips 75, 77 to board 60.

The overall thickness of cases 63, 64 are increased to about 4.5 mm to accommodate second flash memory chip 75.

FIG. 12 is a cross-section of an alternate embodiment with BGA chips mounted to both sides of the board and a cover over the USB pads. The device is as described for FIG. 11, except for cover 65. Cover 65 partially covers metal contacts 42, acting as a metal wrap around the USB connector. Cover 65 may be an extension of case 63 or may be separate. Cover 65 and/or case 63 may be metal or plastic material.

Lead-Free-Process Considerations

The element lead (Plumbium, Pb) is indicated as a hazardous material. Legislatives would like to remove this material within a couple of years, such as from the European Union and Japan after January 2008 or earlier.

The traditional USB plug which has plastic substrate during PCBA process will be shrunk and warped at a temperature of about 240° C. (peak temp of lead-free solder paste), therefore such a USB plug is not suitable for lead-free process.

The slim USB plug doesn't have the plastic substrate during PCBA process and uses a different PCB material to provide a better temperature resistance to the peak temp of 240° C. of the lead-free process. For lead-free processes, surface mount components as well as BGAs don't contain lead in their pins or balls. After the PCBA process, the plastic housing is added and assembled to finish the final product.

### ALTERNATE EMBODIMENTS

Several other embodiments are contemplated by the inventors. For example controller chip 70 could be combined with flash memory chip 77 in a single BGA package. Rather than use a BGA package, the flash-memory die could be directly attached to board 60 with die-wire bonding.

The bottom opening of case 68 (FIGS. 5A-B) may be enlarged so that case 68 is fully open to its perimeter on the bottom. Then cover 40 in FIG. 5A may be extended to cover this larger opening. Inserting board 60 into case 68 may be easier with the larger opening. The larger opening may also be used in other embodiments, such as those of FIGS. 6 and 9. Also, board 60 may not have a cover over it.

Rather than or in addition to snap tabs, adhesive can be used. Pressure or heat sensitive adhesive films can be attached to board 60 or to case 68 where bonding is desired. For example, an adhesive could be brushed on as a liquid or paste, or it could be a double-coated adhesive film such as 3M's 7953 film. A thermal bond film (TBF) such as 3M's TBF-668 could also be used.

Once board 60 and case 68 are pressed together with board 60 in between, the adhesive can be cured by heating the assembly, by pressing the case and board together, or by allowing sufficient time for curing.

Board 60 could also be mounted over the tops of side walls of a lower case. In that variation the edges of board 60 are exposed rather than covered by case 68. In some embodiments board 60 could be the same area or ever larger than case 68, or vice-versa.

Snap-tabs with movable latching teeth or extensions or locking portions may also be used. Different thicknesses and dimensions can be substituted for the examples given. The narrow USB device may have a somewhat varying width, such as within +/−20% of the width at the insertion end.

Rather than mount packaged IC's onto the bottom-side of board 60, unpackaged die may be mounted using die-bonding techniques. Using unpackaged die rather than packaged die may reduce the size and weight of the card.

Various design features such as supporting underside ribs or bumps can be added. A variety of materials may be used for the connector substrate, circuit boards, metal contacts, case, etc. Plastic cases can have a variety of shapes and may partially or fully cover different parts of the circuit board and connector, and can form part of the connector itself. Metal covers rather than plastic may be used in some embodiments. Various features can have a variety of shapes and sizes. Oval, round, square, rectangular, trapezoidal, and other shapes may be used.

A slim connector may be considered “half-height”, since it fits on one side of the female's connector substrate but not on the other side of the female's connector substrate. The actual “half-height” connector may not be exactly half the height of a standard connector, but is considered “half-height” because it engages only half of the female connector. The slim connector may be a reduction in height of only 30-40% rather than exactly half.

The slim connector may be widened to accommodate extra metal contacts to become an extended-USB connector for future USB specification. Moreover, the width of the slim connector can be widened, and the height and metal contacts of the slim connector can be varied, making it into a general-purpose slim connector, for USB, extended-USB, PCI Express, mini PCI Express applications, etc.

Rather than have a flash-memory chip, the USB device may have a wireless communications chip or other kind of chip that supports wireless communications such as Bluetooth or music playback such as for an MP3 player.

There are 4 pins in the current USB pin out definition—VCC, GND, D+, and D−. VCC is the 5V power pin. GND is the ground pin and D+ and D−are the differential data I/O pins. For the USB 2.0 specification, data transfer rates are up to 480M bits/sec, and the power supply current is 500 mA. These might not meet future (or even some current) needs of speed and power associated with some USB devices, such as large flash memory cards.

Additional metal contacts can be added to the new connectors. These additional metal contacts can serve as power, ground, and/or I/O pins which are extensions to the USB specification, or as PCI Express (or mini PCI Express) specifications. Greater power capability can be obtained with (or without) additional power and ground pins (or by a higher power supply current of the existing power pin). Multiple power supplies can also be provided by the additional power and ground pins. The improved power supply capabilities allow more devices and/or more memory chips to be powered. Extra I/O pins can be added for higher bandwidth and data transfer speeds. The additional I/O pins can be used for multiple-bit data I/O communications, such as 2, 4, 8, 12, 16, 32, 64, . . . bits. By adopting some or all of these new features, performance of flash memory cards/devices can be significantly improved. These additional pins could be located behind or adjacent to the existing USB pins, or in various other arrangements. The additional pins could be applied to male and female connectors, both the current or the new slim connectors. New types of flash memory cards/devices can be made with these new connectors, which have the additional pins.

Any advantages and benefits described may not apply to all embodiments of the invention. When the word “means” is recited in a claim element, Applicant intends for the claim element to fall under 35 USC Sect. 112, paragraph 6. Often a label of one or more words precedes the word “means”. The word or words preceding the word “means” is a label intended to ease referencing of claims elements and is not intended to convey a structural limitation. Such means-plus-function claims are intended to cover not only the structures described herein for performing the function and their structural equivalents, but also equivalent structures. For example, although a nail and a screw have different structures, they are equivalent structures since they both perform the function of fastening. Claims that do not use the word “means” are not intended to fall under 35 USC Sect. 112, paragraph 6. Signals are typically electronic signals, but may be optical signals such as can be carried over a fiber optic line.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A narrow card with an integrated slim Universal-Serial-Bus (USB) connector comprising:
a substrate board;
a plurality of metal contacts disposed on a first surface of the substrate board, the plurality of metal contacts for carrying USB signals;
an integrated circuit memory packaged in a Ball Grid Array (BGA) package that has a two-dimensional array of rows and columns of solder balls for electrically connecting and mounting to a second surface of the substrate board, the second surface being a side of the substrate board that is opposite the first surface;
a case for encapsulating the substrate board and the BGA package when assembled; and
an opening in the case that corresponds in location to the plurality of metal contacts, the opening in the case allowing the plurality of metal contacts to make physical contact with metal pads on a female USB socket when inserted.

2. The narrow card with the integrated slim USB connector of claim 1 wherein the substrate board has a first width at an insertion end that contains the plurality of metal contacts;
wherein a width of the BGA package is less than the first width.

3. The narrow card with the integrated slim USB connector of claim 2 wherein the substrate board has a width at a portion of the substrate board containing the BGA package that is within +/−20% of the first width.

4. The narrow card with the integrated slim USB connector of claim 2 wherein the substrate board has the first width for an entire length of the substrate board, wherein the substrate board has a constant width that is substantially determined by the integrated slim Universal-Serial-Bus (USB) connector.

5. The narrow card with the integrated slim USB connector of claim 2 wherein the case is a plastic case formed in a single molding step by molding plastic around the substrate board in a molding fixture that supports the substrate board during molding.

6. The narrow card with the integrated slim USB connector of claim 2 wherein the case is a plastic case, further comprising:
a cover that is bonded to the case during assembly by ultra-sonic bonding, by inserting snap tabs into grooves, or by an adhesive or a thermal-bond film.

7. The narrow card with the integrated slim USB connector of claim 6 wherein the cover contains ridges that first make contact with the case during assembly by ultra-sonic bonding, the ridges being absorbers of ultra-sonic energy that are heated by the ultra-sonic energy, or
wherein the case contains ridges that first make contact with the cover during assembly by ultra-sonic bonding, the ridges being absorbers of the ultra-sonic energy that are heated by the ultra-sonic energy.

8. The narrow card with the integrated slim USB connector of claim 6 wherein the cover contains snap tabs that fit into groves in the case during assembly, or wherein the case contains groves that fit snap tabs in the cover during assembly.

9. The narrow card with the integrated slim USB connector of claim 2 further comprising:
a light window formed by a thinning of plastic in the case, the light window allowing some light from a light-emitting diode to pass through the case;
a light-emitting diode mounted to the substrate board, for generating light for passing through the light window to indicate a status to a user.

10. The narrow card with the integrated slim USB connector of claim 2 wherein the substrate board is a printed-circuit board (PCB) containing wiring traces.

11. The narrow card with the integrated slim USB connector of claim 10 wherein the integrated circuit memory mounted to the second surface of the substrate board comprises:
a flash memory chip with non-volatile memory that retains data when power is removed.

12. The narrow card with the integrated slim USB connector of claim 11 further comprising:
a controller chip mounted on the substrate board, for reading data from and for writing data to the flash memory chip and sending the data over the plurality of metal contacts as USB signals to the female USB socket.

13. A Universal-Serial-Bus (USB) card assembly comprising:
a circuit board having wiring traces, the circuit board having four metal contacts on an insertion end of a contact side of the circuit board, the four metal contacts for connecting to USB contacts in a USB socket when inserted;
a Ball Grid Array (BGA) package containing a flash-memory chip with non-volatile memory, the BGA package mounted to the circuit board;
a case for substantially covering the contact side of the circuit board when assembled;
a cover for substantially covering a reverse side opposite the contact side of the circuit board when assembled;
a contact opening in an insertion end of the case, the contact opening allowing the four metal contacts to contact the USB contacts through the case when inserted into the USB socket; and
wherein the cover is bonded to the case with the circuit board and the BGA package encased between the cover and the case when assembled.

14. The USB card assembly of claim 13 wherein a height of the insertion end of the USB card assembly is less than a standard height of a standard USB male connector,
wherein a width of the insertion end of the USB card assembly is about equal to a width of a chip portion of the USB card assembly that contains the BGA package in a cross-section;
whereby the USB card assembly has a reduced height but a relatively constant width.

15. The USB card assembly of claim 13 further comprising:
ultrasonic protrusions on a first case that first initially contact a second case during assembly, the ultrasonic protrusions partially melting to bond the cover to the case when ultrasonic energy is applied during assembly;
wherein the first case is the cover and the second case is the case, or the first case is the case and the second case is the cover.

16. The USB card assembly of claim 13 further comprising:
snap protrusions on a first case;
grooves on a second case;
the snap protrusions fitting into the grooves during assembly;
wherein the first case is the cover and the second case is the case, or the first case is the case and the second case is the cover.

17. The USB card assembly of claim 13 further comprising:
a thermal-bond film applied to a first case before assembly to bond to a second case;
wherein the first case is the cover and the second case is the case, or the first case is the case and the second case is the cover.

18. The USB card assembly of claim 13 further comprising:
a second opening in the case for fitting the circuit board through during assembly into the case;
wherein the cover is for closing the second opening.

19. A narrow Universal-Serial-Bus (USB) plug card comprising:
circuit board means for supporting integrated circuits on a bottom side, having an insertion end for insertion into a USB socket;
Ball Grid Array (BGA) package means for encapsulating one of the integrated circuits, the BGA package means having solder balls in a two-dimensional array for interconnect to the circuit board means;
metal contactor means, formed on the insertion end of a top side of the circuit board means, for making electrical contact with a USB socket when the insertion end is inserted into the USB socket;
top body means, formed from plastic, for partially encapsulating the top side of the circuit board means; and
bottom body means, formed from plastic, for encapsulating the bottom side of the circuit board means.

20. The narrow USB plug card of claim 19 wherein the top body means is bonded to the bottom body means to enclose the circuit board means, wherein an ultrasonic, an adhesive, a molding, or a snap-together bonding process bonds the top body means to the bottom body means.
